(19) United States
(12) Patent Application Publication
(10) Pub. No.: US 2025/0293452 A1
(43) Pub. Date: Sep. 18, 2025

(54) PIN RETENTION MECHANISM

(71) Applicant: Cox Automotive, Inc., Atlanta, GA (US)

(72) Inventors: Connor Taylor, Atlanta, GA (US); Sarah Hake, Atlanta, GA (US)

(21) Appl. No.: 19/081,692

(22) Filed: Mar. 17, 2025

Related U.S. Application Data
(60) Provisional application No. 63/565,904, filed on Mar. 15, 2024.

(51) Int. Cl. H01R 13/436; H01R 12/71; H01R 13/24; H01R 13/62; H01R 13/631; H01R 43/26

(52) U.S. Cl. CPC H01R 13/4362; H01R 12/714; H01R 13/2471; H01R 13/631; H01R 43/26; H01R 13/6205

(57) ABSTRACT

An example interchangeable pin connector includes a first plate including a plurality of holes; a plurality of pins disposed in the plurality of holes; and a retainer plate comprising a plurality of slots, wherein the retainer plate is movable relative to the first plate between (i) a locked configuration wherein a narrow end the plurality of slots aligns with the plurality of pins to retain the plurality of pins within the plurality of holes (ii) an unlocked configuration wherein a wide end of the plurality of slots aligns with the plurality of pins such that the plurality of pins is releasable from the plurality of holes.

### CROSS-REFERENCE TO RELATED APPLICATIONS

This application claims the benefit of U.S. provisional patent application No. 63/565,904, filed on Mar. 15, 2024, and titled “PIN RETENTION MECHANISM,” the disclosure of which is expressly incorporated herein by reference in its entirety.

### BACKGROUND

Electrical cables can carry data and/or energy from one location to another. Electrical connectors are used to join electrical cables together. Electrical connectors (e.g., plugs) can be used to join electrical cables together so that data and/or energy can flow from one electrical cable to another electrical cable.

Often, electrical connectors use pin contacts or pins to facilitate the flow of data and/or energy. For example, a connector may include an array of pins on one side of the connector and an array of corresponding electrical contacts on the other side of the connector. Each pin may be permanently, or semi-permanently, coupled to the electrical connectors or a base structure thereof (e.g., soldered). However, the life cycle of an electrical connector is limited. Therefore, a need exists for improved electrical connectors.

### SUMMARY

Provided herein are devices, systems, and methods for pin retention and replacement in electrical connectors. For example, described herein are devices, systems, and methods for providing and retaining an array of pins in an electrical connector and/or testing module. Further described herein are devices, systems, and methods for quickly and efficiently replacing pins of an array of pins without replacing the entire electrical connector.

In some implementations, an interchangeable pin connector is disclosed, the interchangeable pin connector including: a first plate including a plurality of holes, including a first hole; a plurality of pins, including a first pin disposed in the first hole; and a retainer plate including a plurality of slots, including a first slot. The retainer plate is movable relative to the first plate between (i) a locked configuration wherein a narrow end of the first slot aligns with the first pin to retain the first pin within the first hole and (ii) an unlocked configuration wherein a wide end of the first slot aligns with the first pin such that the first pin is releasable from the first hole.

In some implementations, the interchangeable pin connector further includes a second plate disposed on a side of the retainer plate opposite the first plate.

In some implementations, the second plate defines a recess within which the retainer plate is disposed.

In some implementations, the first pin includes a flange, and the narrow end of the first slot is configured to capture at least a portion of the flange of the first pin.

In some implementations, the interchangeable pin connector further includes a base plate coupled to the first plate.

In some implementations, the base plate includes a spring coupled between the base plate and the first plate.

In some implementations, the retainer plate includes a first retainer plate section and a second retainer plate section, wherein the first retainer plate section is separately movable from the second retainer plate section.

In some implementations, the first retainer plate section and the second retainer plate section are configured to each retain a different portion of pins of the plurality of pins.

In some implementations, the plurality of slots includes a first set of slots with a first length, and a second set of slots with a second length.

In some implementations, the plurality of slots is configured so that moving the retainer plate different distances can lock or unlock different combinations of pins from the plurality of pins.

In some implementations, the plurality of slots is configured as key slots, wherein each key slot includes a narrow end and a wide end opposite the narrow end.

In some implementations, the first pin is a spring pin including a contact on a distal end thereof, wherein the contact is configured to electrically couple to a printed circuit board.

According to another implementation, an electrical coupler system is disclosed, the electrical coupler system including: a target including: a printed circuit board on a first side of the target including a plurality of pads, including a first pad; and at least one cable connector on a second side of the target opposite the first side of the target, wherein the at least one cable connector is in electrical communication with the printed circuit board; and an interchangeable pin connector, including: a first plate including a plurality of holes, including a first hole; a plurality of pins, including a first pin disposed in the first hole; and a retainer plate including a plurality of slots, including a first slot, wherein the retainer plate is movable relative to the first plate between (i) a locked configuration wherein a narrow end of the first slot aligns with the first pin to retain the first pin within the first hole and (ii) an unlocked configuration wherein a wide end of the first slot aligns with the first pin such that the first pin is releasable from the first hole.

In some implementations, the target further includes at least one alignment hole and the interchangeable pin connector includes at least one alignment pin, and the target and the interchangeable pin connector are mechanically couplable via the at least one alignment hole and the at least one alignment pin.

In some implementations, the at least one alignment pin of the interchangeable pin connector is tapered to compensate for misalignment between the interchangeable pin connector and the target.

In some implementations, the target and the interchangeable pin connector are electrically couplable via the first pin of the interchangeable pin connector and the first pad of the printed circuit board of the target.

In some implementations, the interchangeable pin connector includes a plate including a hole; a pin disposed in the hole; and a retainer plate including a slot, wherein the retainer plate is movable relative to the plate between (i) a locked configuration wherein a narrow end of the slot aligns with the pin to retain the pin within the hole and (ii) an unlocked configuration wherein a wide end of the slot aligns with the pin such that the pin is releasable from the hole.

According to another implementation, a method of coupling an electrical coupler system is disclosed, the method including: providing a target including a printed circuit board on a first side of the target including a pad; and at least one cable connector on a second side of the target opposite the first side of the target, wherein the at least one cable connector is in electrical communication with the printed circuit board; providing an interchangeable pin connector, including a plate including a hole, a pin disposed in the hole, and a retainer plate including a slot, wherein the retainer plate is movable relative to the plate; and coupling the interchangeable pin connector to the target such that a contact of the pin electrically connects to the pad of the printed circuit board of the target.

In some implementations, the method further includes: when the target and the interchangeable pin connector are decoupled, moving the retainer plate from (i) a locked configuration wherein a narrow end the slot aligns with the pin to retain the pin within the hole towards (ii) an unlocked configuration wherein a wide end of the slot aligns with the pin such that the pin is releasable from the hole; and replacing the pin with a second pin.

In some implementations, coupling the interchangeable pin connector to the target includes inserting an alignment pin of the interchangeable pin connector into an alignment opening of the target.

Additional advantages will be set forth in part in the description which follows or may be learned by practice. The advantages will be realized and attained by means of the elements and combinations particularly pointed out in the appended claims. It is to be understood that both the foregoing general description and the following detailed description are exemplary and explanatory only and are not restrictive, as claimed.

### BRIEF DESCRIPTION OF DRAWINGS

FIG. 1A illustrates an example coupler, including a target and interchangeable pin connector, according to one implementation of the present disclosure.

FIG. 1B illustrates a perspective view of the example target and interchangeable pin connector of FIG. 1A.

FIG. 2 illustrates an example target including a PCB having wire solder joints (e.g., pads and cones), according to one implementation.

FIG. 3 illustrates a pin including a contact and flange, according to one implementation.

FIG. 4A illustrates a retainer plate with slots configured to hold pins in place, where the slots are positioned so that the pins are unlocked, according to one implementation.

FIG. 4B illustrates the retainer plate of FIG. 4A, where the slots of the retainer plate are positioned so that the pins are locked, according to one implementation.

FIG. 5A illustrates an interchangeable pin connector in a locked position, according to one implementation.

FIG. 5B illustrates the interchangeable pin connector of FIG. 5A in an unlocked position.

FIG. 6A illustrates a side cross sectional view of an interchangeable pin connector, according to one implementation.

FIG. 6B illustrates a perspective cross sectional view of an interchangeable pin connector, according to one implementation.

Various objects, aspects, features, and advantages of the disclosure will become more apparent and better understood by referring to the detailed description taken in conjunction with the accompanying drawings, in which like reference characters identify corresponding elements throughout. In the drawings, like reference numbers generally indicate identical, functionally similar, and/or structurally similar elements.

### DETAILED DESCRIPTION

Described herein are devices, systems, and methods for retaining and replacing pins within an electrical connector. In some examples, the electrical connectors described herein may be a portion of a coupler and/or an electrical connector device for coupling one cable to another cable or another device. In some examples, the pin connector described herein is configured for coupling to and collecting data from battery banks/arrays (e.g., for testing the life, power, efficiency, and/or operation of the batteries). However, the specific examples and applications described herein are illustrative only, and a variety of applications in a variety of industries are contemplated by this disclosure.

When testing batteries (e.g., electric vehicle batteries or banks/arrays of electric vehicle batteries), a testing device or testing module may be provided. The testing module may be used to connect to a variety of batteries (e.g., various numbers of batteries, various types of batteries, various brands of electric vehicles, and/or various stages of life of the batteries). For example, a single testing module may be configured to couple to several different battery banks from several different electric vehicles and/or battery manufacturers. The diverse battery types may result in diverse cable and/or connector usage. The various connections may be performed successively such that the testing module performs many different cycles of testing in a given time period. Therefore, the testing module must withstand a variety of electrical load levels and cycles across several iterations of connecting and disconnecting from the battery bank.

In some examples, the testing module is configured to couple to a power input/output (e.g., positive and negative connections) and a signal input/output. The testing module may be further connected to a controller or computer configured to collect and analyze data about the power and/or signal flow of the battery bank being tested. The testing module may include an array of connectors (e.g., pins) configured to electrically and mechanically couple to an array of contacts (e.g., on a printed circuit board).

Across multiple testing operations, the testing module may experience an unexpected disruption in the testing operation. For example, a connector may experience a higher voltage or amperage than expected, or a connector may experience a mechanical force that results in damage. In a standard operating procedure, a damaged connection is replaced before the next testing operation. Alternatively, in some implementations, the connectors of the testing module may be replaced to alter the setup or configuration of the connectors for a different battery, vehicle, or test. In existing systems, the replacement of a single connector may result in the replacement of the entire electrical connector (or the entire testing module, or an entire array of connectors) due to the permanent or semi-permanent connections between the connectors and the testing module. For example, the connectors may be pins that are soldered to a portion of the testing module. Thus, replacing a pin may involve carefully removing and re-soldering a replacement pin (a time-consuming process), or simply replacing an entire array of pins (an expensive process).

Disclosed herein are devices, systems, and methods for retaining and replacing single pins or groups of pins without replacing an entire connector of the testing module. For example, in the case of a malfunction or a configuration change, a testing module of this disclosure may be unlocked so that a single pin or group of pins may be removed. Furthermore, the configuration of the array of pins may be revised depending on the application or test to be performed. The pins can be quickly and efficiently switched between a locked and unlocked configuration to speed up testing operations and changeover between testing operations.

### Example Device

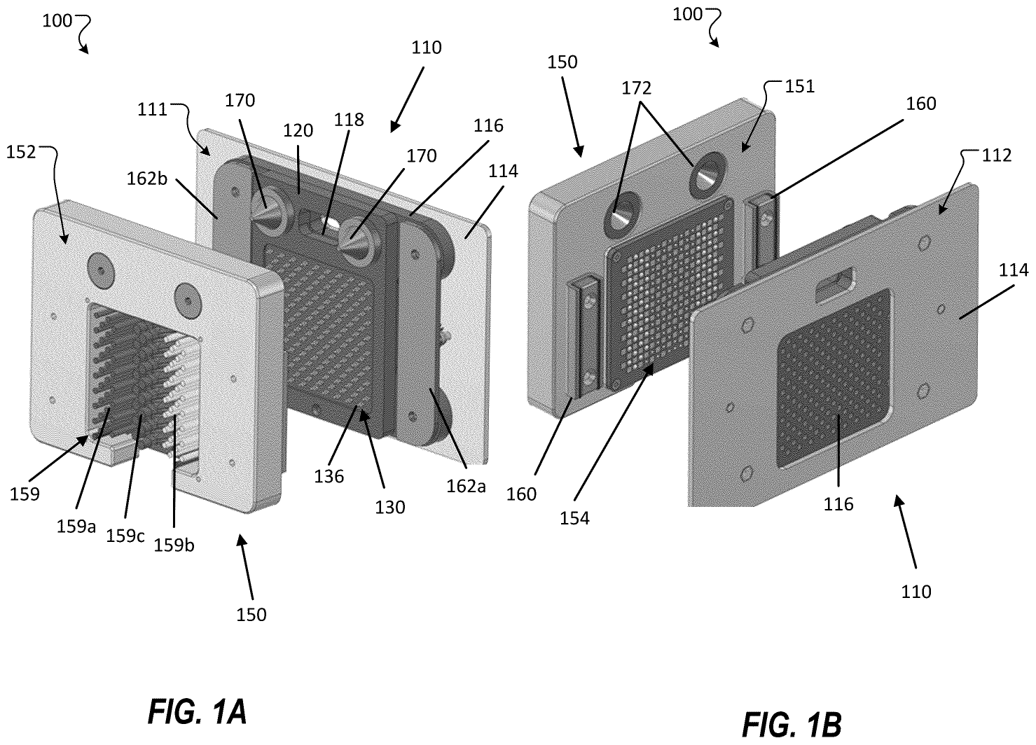

FIGS. 1A and 1B illustrate an example coupler 100, according to one implementation of the present disclosure. The coupler 100 includes an interchangeable pin connector 110 and a target 150. The coupler 100 may be used, for example, in a battery testing module wherein the target 150 couples to one or more cables in electrical communication with a battery bank. The interchangeable pin connector 110 may be in electrical communication with the target 150 on one end and a controller or computer on the other end to receive and analyze power and/or data signals from the battery bank. In some implementations, the battery bank is an electric vehicle battery bank. In some implementations, the testing modules perform a testing operation to determine the estimated life remaining and maximum power output of the battery bank.

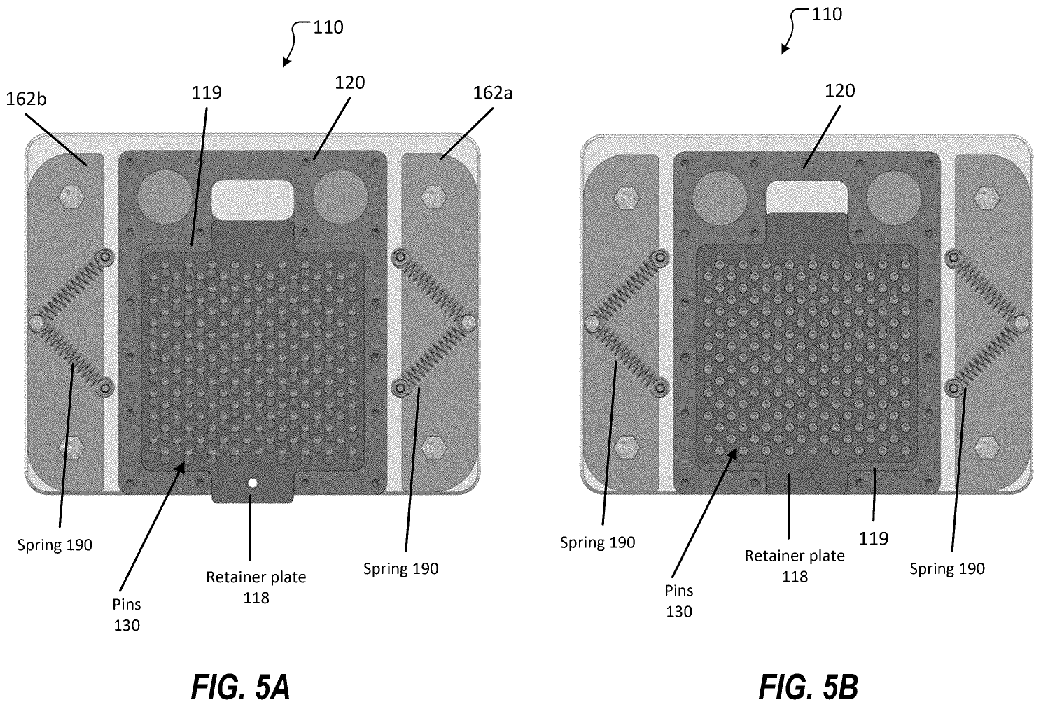

The interchangeable pin connector 110 has a first side 111 (e.g., a contact side or a mating side) and a second side 112 opposite from the first side 111. The interchangeable pin connector 110 includes a base plate 114, a first plate 116, a retainer plate 118, a second plate 120 and an array of pins 130. The first plate 116 is coupled to and extends from the base plate 114 on the first side 111 of the interchangeable pin connector 110. The second plate 120 is coupled to the first plate 116 to hold the retainer plate 118 in between the first plate 116 and the second plate 120. The retainer plate 118 sits within a recess 119 (shown in FIGS. 5A and 5B) defined in the second plate 120. The pins 130 extend through a plurality of openings (e.g., an array of openings) defined in each of the first plate 116, the second plate 120, and retainer plate 118.

The interchangeable pin connector 110 further includes alignment pins 170 protruding from the second plate 120 on the first side 111 of the interchangeable pin connector 110. The alignment pins 170 shown in FIG. 1A have a conical shape, but they may be of any other suitable shape. In other implementations, the coupler of this disclosure may not include alignment pins.

The interchangeable pin connector 110 of the coupler 100 further includes side members 162a and 162b disposed on either side of the second plate 120. The side members 162a, 162b are rigidly coupled to the base plate 114 via a fastener.

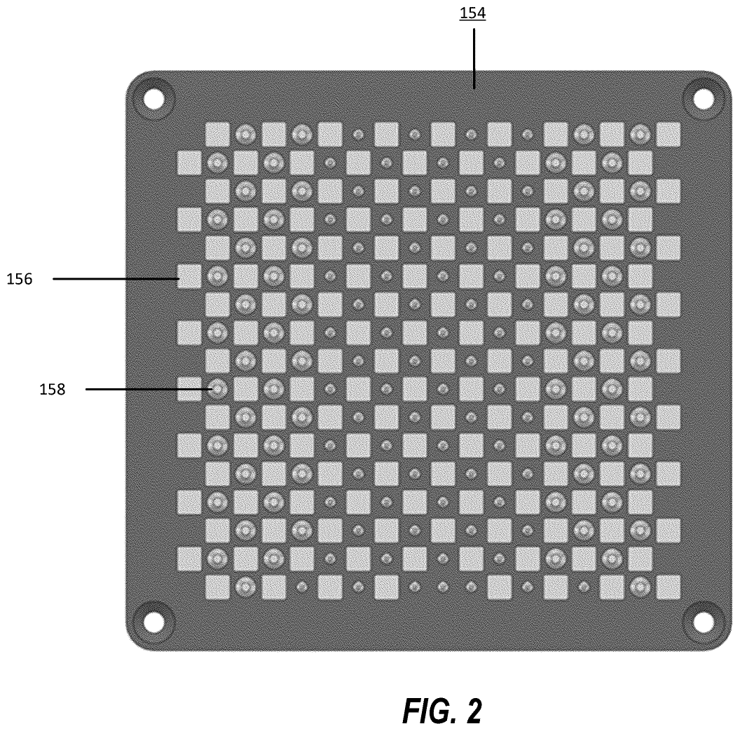

The target 150 includes a first side 151 and a second side 152 opposite from the first side 151. The target 150 includes a printed circuit board (PCB) 154 coupled to the first side 151 of the target 150. The PCB 154 includes a plurality of wire solder joints, including pads 156 and cones 158 (shown in more detail in FIG. 2), formed on the PCB 154. The connection points may be formed with a soldered connection (e.g., a solder fillet securing the component lead into the PCB, optionally including copper foil). The cones 158 can optionally be attachment points (e.g., solder joints) where a wire is joined to the PCB 154. Optionally, the PCB 154 can include traces that can electrically connect the pads and cones. Any combination of pads and/or cones on the target can be joined by the traces. The PCB 154 can optionally be a multi-layer PCB and/or reinforced PCB. Optionally, the multi-layer PCB can be configured for multiple layers of traces and/or for greater heat dissipation than a single layer PCB.

On the second side 152 of the target 150, opposite of the PCB 154, cable connectors 159 are provided in electrical communication with the PCB 154. The cable connectors 159 include a negative power connector 159a, a positive power connector 159b, and a signal connector 159c. Each of the cable connectors 159 is configured to couple to a terminal connection (e.g., from a cable coupled to an array of batteries for testing).

The target 150 further includes magnets 160 on the first side 151. The target 150 further includes alignment holes 172 defined on the first side 151 of the target 150. The alignment holes 172 are conical in shape corresponding to the alignment pins 170 of the interchangeable pin connector 110.

The interchangeable pin connector 110 and the target 150 can be coupled to each other mechanically and electrically. When the interchangeable pin connector 110 and the target 150 are coupled together, with the first side 111 of the interchangeable pin connector 110 facing the first side 151 of the target 150, the alignment pins 170 engage with the alignment holes 172. The corresponding conical shape of the alignment pins 170 and the alignment holes 172 facilitates mechanical engagement and corrects for small misalignments between the target 150 and the interchangeable pin connector 110. Furthermore, the magnets 160 couple to the base plate 114 of the interchangeable pin connector 110 to strengthen the connection between the interchangeable pin connector 110 and the target 150.

In other implementations, the alignment pins and alignment holes can be on either side of the coupler, or on both sides of the coupler. For example, the interchangeable pin connector can include alignment holes and the target can include alignment pins. In other implementations, the shape of the alignment pins and alignment holes may be different (e.g., a pyramid shape, a frustoconical shape, or any other shape having a taper to correct for misalignment).

When coupled together, the pins 130 of the interchangeable pin connector 110 contact the pads 156 of the PCB 154 on the target 150. As shown in FIG. 2, the PCB 154 can include any number of pads 156 in any arrangement that can be configured to contact the pins 130 of the interchangeable pin connector 110.

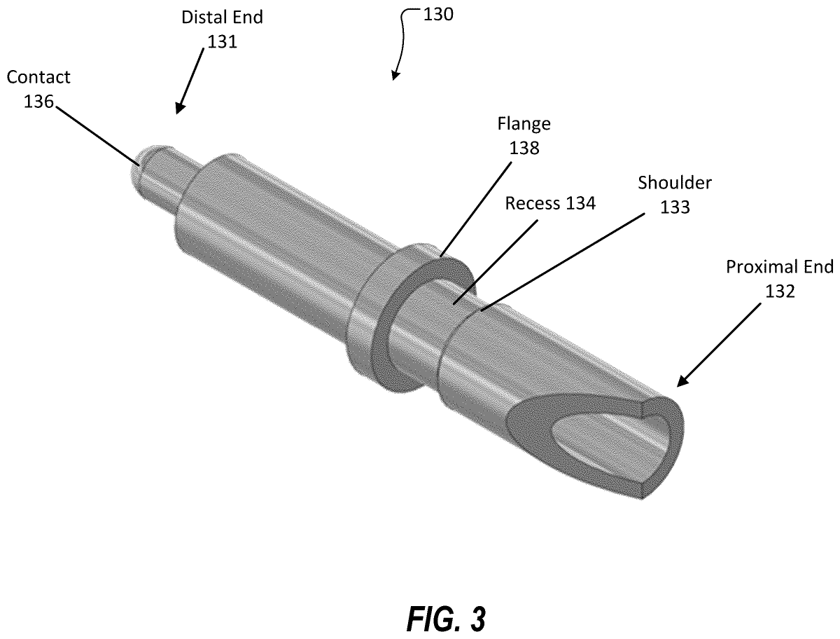

FIG. 3 shows a pin 130 of the coupler 100. The pin 130 includes a distal end 131 and a proximal end 132 opposite and spaced apart from the distal end 131. A flange 138 is formed between the proximal end 132 and the distal end 131. The flange 138 defines a flange diameter larger than that of other pin elements. Adjacent to the flange 138 is a recess 134 defined by the flange 138 on a side closer to the distal end 131 and a shoulder 133 on a side closer to the proximal end 132. However, in other implementations, the pin does not include a recess but instead maintains a constant diameter across at least one portion of the pin adjacent to the flange.

The pin 130 further includes a contact 136 located at the distal end 131 of the pin 130. The contact 136 is configured to provide an electrical connection (e.g., through the pin 130). In some implementations, the proximal end of the pin is configured to reversibly couple to a wire, PCB, or other electrical connection. The pin 130 can include a spring-loaded pin having an internal spring. The spring loaded pin 130 may be configured to apply a force on the contact 136 towards the distal end 131 of the pin 130.

The pins 130 are installed through corresponding holes in the first plate 116, the second plate 120, and the retainer plate 118. As shown in FIG. 1A, the contact 136 of the pin 130 extends out of the second plate 120 on the first side 111 of the interchangeable pin connector 110. Thus, the contact 136 of the pins 130 are configured to contact and form an electrical connection with the pads 156 or cones 158 of the PCB 154 of the target 150.

As described herein, the pin 130 can be configured to be removable and interchangeable from an interchangeable pin connector (e.g., the interchangeable pin connector 110 shown in FIG. 1A and FIG. 1B). For example, in the case of a broken or malfunctioning pin, the pin 130 disclosed herein is removable from the interchangeable pin connector 110 to be replaced. Rather than removal via destructive means or solder removal, the pins 130 may be easily removed by unlocking the retainer plate, as shown in FIGS. 3A and 3B.

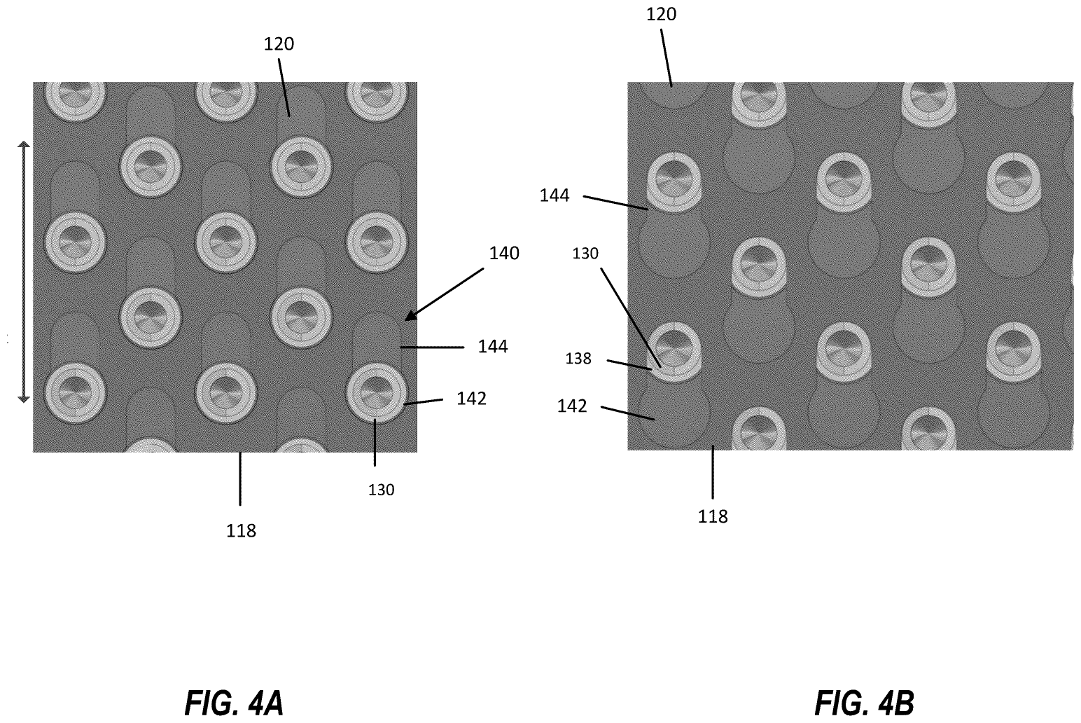

With reference to FIGS. 4A and 4B, a detailed view of the retainer plate 118 of the interchangeable pin connector 110 of FIGS. 1A and 1B is shown. FIG. 4A shows an unlocked configuration of the retainer plate 118, and FIG. 4B shows a locked configuration of the retainer plate 118. The retainer plate 118 of the interchangeable pin connector 110 is movable, relative to the second plate 120, between the locked and unlocked configurations.

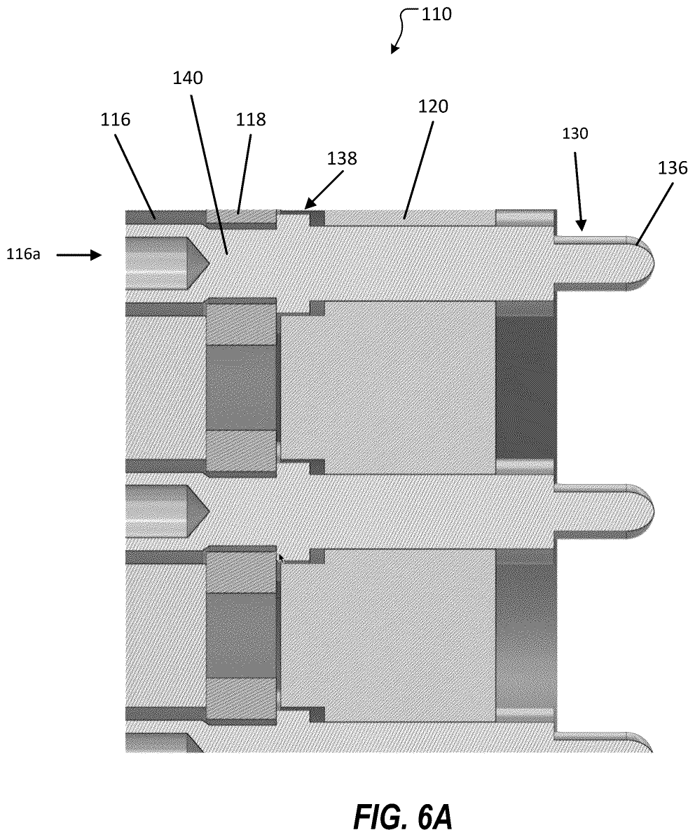

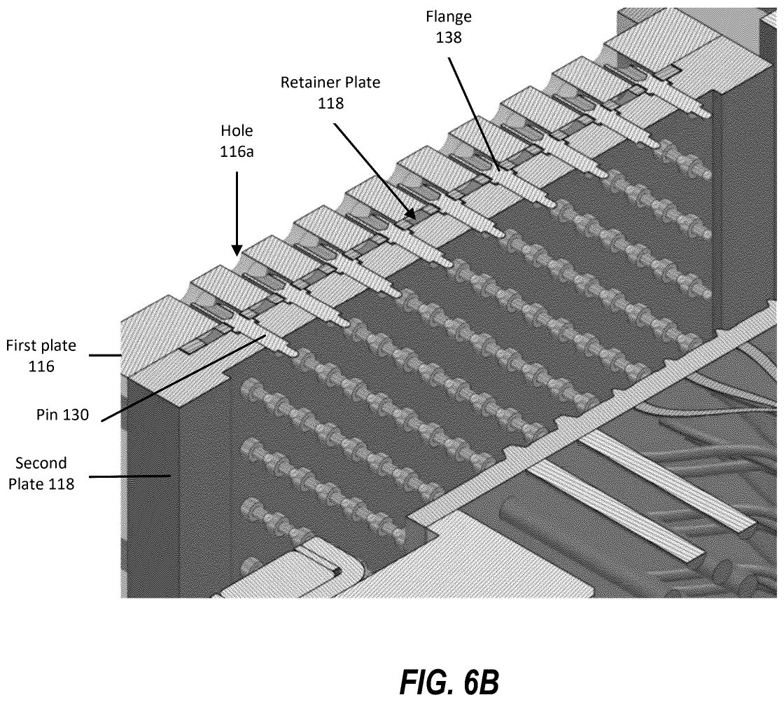

The retainer plate 118 includes slots 140 defined and formed in the retainer plate 118. The slots 140 each include a wide end 142 and a narrow end 144. The pins 130 are received in holes formed in the interchangeable pin connector 110 (e.g., the holes 116a in the first plate 116 shown in FIG. 6B). When the pin 130 is positioned in the wide end 142 of a slot 140, as shown in FIG. 4A, the pin 130 can be removed from the retainer plate 118. In other words, in the unlocked configuration, the wide end 142 of the slot 140 has a diameter larger than the largest diameter of the pin 130 (including, for example, the diameter of the flange 138 of the pin 130).

When the pin 130 is in the narrow end 144 of the slot 140, a flange 138 of the pin 130 is captured by the retainer plate 118 as shown in FIG. 4B. In other words, when moving from the unlocked to the locked configuration, the retainer plate 118 slides with respect to the first plate 116, and each of the pins 130 moved and locked in the narrow end 144 of the slots 140 of the retainer plate 118. The narrow end 144 of the slots 140 has a diameter less than the diameter of the flange 138 of the pin 130. Thus, in the locked configuration, the narrow end 144 of the slot 140 sits within the recess 134 of the pin 130 such that the diameter of the shoulder 133 of the pin 130 is larger than the diameter of the narrow end 144. In the locked configuration, the retainer plate 118 restricts the movement of the pin 130 with respect to the first plate 116, the retainer plate 118, and the second plate 120.

In other implementations, an additional locking pin is provided to provide an additional mechanical lock to the interchangeable pin connector. For example, in some implementations, the first and second plates may include a locking hole offset from the plurality of holes of the pins. In some implementations, the locking hole may align with the wide end of one of the slots such that a separate locking pin may be inserted into the locking hole to extend through the wide end of the corresponding slot. Once inserted, the locking pin provides a mechanical stop preventing the pins from sliding unexpectedly from the narrow end to the wide end of the slots (e.g., when the coupler is dropped or hit unexpectedly).

As a non-limiting example, as measured from the narrow end 144 to the wide end 142, a first slot can be 1 mm long, a second slot can be 2 mm long, a third slot can be 3 mm long, and a fourth slot can be 4 mm long. As the retainer plate including the slots is moved, the slots of different lengths can unlock or lock the respective pins in each slot sequentially, so that, for example, the first slot is unlocked first, then the second, then the third, and then the fourth. The present disclosure further contemplates that the slots can have other shapes-for example, the slots can be shaped with alternating narrow sections and wide sections so that, as the pin moves along a single direction, the pin is locked and unlocked repeatedly.

In some implementations, the retainer plate can be split into a number of sections where the sections are independently movable from one another. For example, a row/column of pins can be configured so that the row is unlocked or locked by a first retainer plate, while an adjacent row/column of pins is unlocked or locked by a second retainer plate. Having separate retainer plates provides for faster and more efficient repair times (e.g., a technician can easily perform a pin replacement by unlocking only a portion of the pins). Separate retainer plates also ensures that the majority of the pins remain aligned while only a target area of pins are unlocked during a replacement.

With reference to FIGS. 5A and 5B, a cutaway view of an interchangeable pin connector 110 is shown. The interchangeable pin connector 110 includes the retainer plate 118 and pins 130 described with reference to FIGS. 1A-4B. In FIG. 5A, the retainer plate 118 is positioned so that the pins 130 are in a locked position, and in FIG. 5B the retainer plate 118 is positioned so that the pins 130 are in an unlocked position.

As shown in FIG. 5A and FIG. 5B, the interchangeable pin connector 110 includes springs 190. The springs 190 are coupled on one end to the base plate 114 and on the opposite end to the first plate 116 of the interchangeable pin connector 110. The springs 190 facilitate planar movement and alignment of the interchangeable pin connector 110 with respect to the target 150. The springs 190 are configured to allow the base plate 114 and the side members 162a, 162b to float relative to the rest of the interchangeable pin connector 110 (e.g., the first plate 116 and the pins 130). The springs 190 are configured such that the pins 130 can be aligned with a target 150 (e.g., with assistance from the alignment pins 170 and alignment holes 172). For example, if a base plate 114 is rigidly mounted to a cart, and a target 150 is rigidly mounted to a station, then this floating allows for lateral misalignment and/or height differences between the cart and the station.

With reference to FIG. 6A, a cross sectional view is shown of an interchangeable pin connector 110 including the first plate 116, the retainer plate 118, and the second plate 120, and a pin 130. The second plate 120 is positioned opposite the first plate 116 so that the second plate 120 and the first plate 116 surround the retainer plate 118. The retainer plate 118 further sits within the recess 119 defined in the first plate 116.

As described with reference to FIG. 4A and FIG. 4B, as the retainer plate 118 moves relative to the pin 130, the slot 140 can move relative to the flange 138 of the pin 130, locking and unlocking the pin 130 from the second plate 120. When the pin 130 is unlocked, the pin 130 can be removed from the second plate 120 and replaced (e.g., to replace a damaged or worn pin with a new one).

FIG. 6B illustrates an example perspective cutaway view of the implementation of the present disclosure illustrated in FIG. 6A.

The present disclosure contemplates that the first plate 116, the second plate 120, and/or the retainer plate 118 can be made from different materials, or the same materials. Optionally, a fiberglass (e.g., FR4 fiberglass), resin, and/or plastic is used to form the first plate 116, the second plate 120, and/or retainer plate 118.

### Configuration of Certain Implementations

The construction and arrangement of the systems and methods as shown in the various implementations are illustrative only. Although only a few implementations have been described in detail in this disclosure, many modifications are possible (e.g., variations in sizes, dimensions, structures, shapes, and proportions of the various elements, values of parameters, mounting arrangements, use of materials, colors, orientations, etc.). For example, the position of elements may be reversed or otherwise varied, and the nature or number of discrete elements or positions may be altered or varied. Accordingly, all such modifications are intended to be included within the scope of the present disclosure. The order or sequence of any process or method steps may be varied or re-sequenced according to alternative implementations. Other substitutions, modifications, changes, and omissions may be made in the design, operating conditions, and arrangement of the implementations without departing from the scope of the present disclosure.

The present disclosure contemplates methods, systems, and program products on any machine-readable media for accomplishing various operations. The implementations of the present disclosure may be implemented using existing computer processors, or by a special purpose computer processor for an appropriate system, incorporated for this or another purpose, or by a hardwired system. Implementations within the scope of the present disclosure include program products including machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures, and which can be accessed by a general purpose or special purpose computer or other machine with a processor.

When information is transferred or provided over a network or another communications connection (either hardwired, wireless, or a combination of hardwired or wireless) to a machine, the machine properly views the connection as a machine-readable medium. Thus, any such connection is properly termed a machine-readable medium. Combinations of the above are also included within the scope of machine-readable media. Machine-executable instructions include, for example, instructions and data which cause a general-purpose computer, special purpose computer, or special purpose processing machines to perform a certain function or group of functions.

Although the figures show a specific order of method steps, the order of the steps may differ from what is depicted. Also, two or more steps may be performed concurrently or with partial concurrence. Such variation will depend on the software and hardware systems chosen and on designer choice. All such variations are within the scope of the disclosure. Likewise, software implementations could be accomplished with standard programming techniques with rule-based logic and other logic to accomplish the various connection steps, processing steps, comparison steps and decision steps.

It is to be understood that the methods and systems are not limited to specific synthetic methods, specific components, or to particular compositions. It is also to be understood that the terminology used herein is for the purpose of describing particular implementations only and is not intended to be limiting.

As used in the specification and the appended claims, the singular forms “a,” “an” and “the” include plural referents unless the context clearly dictates otherwise. Ranges may be expressed herein as from “about” one particular value, and/or to “about” another particular value. When such a range is expressed, another implementation includes from the one particular value and/or to the other particular value. Similarly, when values are expressed as approximations, by use of the antecedent “about,” it will be understood that the particular value forms another implementation. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not. Throughout the description and claims of this specification, the word “comprise” and variations of the word, such as “comprising” and “comprises,” means “including but not limited to,” and is not intended to exclude, for example, other additives, components, integers or steps. “Exemplary” means “an example of” and is not intended to convey an indication of a preferred or ideal implementation. “Such as” is not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific implementation or combination of implementations of the disclosed methods.

1. An interchangeable pin connector, comprising:
a first plate comprising a plurality of holes, including a first hole;
a plurality of pins, including a first pin disposed in the first hole; and
a retainer plate comprising a plurality of slots, including a first slot,
wherein the retainer plate is movable relative to the first plate between (i) a locked configuration wherein a narrow end of the first slot aligns with the first pin to retain the first pin within the first hole and (ii) an unlocked configuration wherein a wide end of the first slot aligns with the first pin such that the first pin is releasable from the first hole.

2. The interchangeable pin connector of claim 1, further comprising a second plate disposed on a side of the retainer plate opposite the first plate.

3. The interchangeable pin connector of claim 2, wherein the second plate defines a recess within which the retainer plate is disposed.

4. The interchangeable pin connector of claim 1, wherein the first pin comprises a flange, and wherein the narrow end of the first slot is configured to capture at least a portion of the flange of the first pin.

5. The interchangeable pin connector of claim 1, further comprising a base plate coupled to the first plate.

6. The interchangeable pin connector of claim 5, wherein the base plate comprises a spring coupled between the base plate and the first plate.

7. The interchangeable pin connector of claim 1, wherein the retainer plate comprises a first retainer plate section and a second retainer plate section, wherein the first retainer plate section is separately movable from the second retainer plate section.

8. The interchangeable pin connector of claim 7, wherein the first retainer plate section and the second retainer plate section are configured to each retain a different portion of pins of the plurality of pins.

9. The interchangeable pin connector of claim 1, wherein the plurality of slots comprises a first set of slots with a first length, and a second set of slots with a second length.

10. The interchangeable pin connector of claim 1, wherein the plurality of slots is configured so that moving the retainer plate different distances can lock or unlock different combinations of pins from the plurality of pins.

11. The interchangeable pin connector of claim 1, wherein the plurality of slots is configured as key slots, wherein each key slot comprises a narrow end and a wide end opposite the narrow end.

12. The interchangeable pin connector of claim 1, wherein the first pin is a spring pin comprising a contact on a distal end thereof, wherein the contact is configured to electrically couple to a printed circuit board.

13. An electrical coupler system comprising:
a target comprising:
a printed circuit board on a first side of the target including a plurality of pads, including a first pad; and
at least one cable connector on a second side of the target opposite the first side of the target, wherein the at least one cable connector is in electrical communication with the printed circuit board; and
an interchangeable pin connector, comprising:
a first plate comprising a plurality of holes, including a first hole;
a plurality of pins, including a first pin disposed in the first hole; and
a retainer plate comprising a plurality of slots, including a first slot,
wherein the retainer plate is movable relative to the first plate between (i) a locked configuration wherein a narrow end of the first slot aligns with the first pin to retain the first pin within the first hole and (ii) an unlocked configuration wherein a wide end of the first slot aligns with the first pin such that the first pin is releasable from the first hole.

14. The electrical coupler system of claim 13, wherein the target further comprises at least one alignment hole and the interchangeable pin connector comprises at least one alignment pin,
wherein the target and the interchangeable pin connector are mechanically couplable via the at least one alignment hole and the at least one alignment pin.

15. The electrical coupler system of claim 14, wherein the at least one alignment pin of the interchangeable pin connector is tapered to compensate for misalignment between the interchangeable pin connector and the target.

16. The system of claim 13, wherein the target and the interchangeable pin connector are electrically couplable via the first pin of the interchangeable pin connector and the first pad of the printed circuit board of the target.

17. An interchangeable pin connector, comprising:
a plate comprising a hole;
a pin disposed in the hole; and
a retainer plate comprising a slot,
wherein the retainer plate is movable relative to the plate between (i) a locked configuration wherein a narrow end of the slot aligns with the pin to retain the pin within the hole and (ii) an unlocked configuration wherein a wide end of the slot aligns with the pin such that the pin is releasable from the hole.

18. A method of coupling an electrical coupler system, the method comprising:
providing a target comprising a printed circuit board on a first side of the target including a pad; and at least one cable connector on a second side of the target opposite the first side of the target, wherein the at least one cable connector is in electrical communication with the printed circuit board;
providing an interchangeable pin connector, comprising a plate comprising a hole, a pin disposed in the hole, and a retainer plate comprising a slot, wherein the retainer plate is movable relative to the plate; and
coupling the interchangeable pin connector to the target such that a contact of the pin electrically connects to the pad of the printed circuit board of the target.

19. The method of claim 18, further comprising:
when the target and the interchangeable pin connector are decoupled, moving the retainer plate from (i) a locked configuration wherein a narrow end the slot aligns with the pin to retain the pin within the hole towards (ii) an unlocked configuration wherein a wide end of the slot aligns with the pin such that the pin is releasable from the hole; and
replacing the pin with a second pin.

20. The method of claim 18, wherein coupling the interchangeable pin connector to the target comprises inserting an alignment pin of the interchangeable pin connector into an alignment opening of the target.
